(19) United States
(12) Patent Application Publication
(10) Pub. No.: US 2024/0275112 A1
(43) Pub. Date: Aug. 15, 2024

(54) CABLE ASSEMBLY CONTAINING SELF-CALIBRATION DATA

(71) Applicant: Teradyne, Inc., North Reading, MA (US)

(72) Inventors: Brian Charles Wadell, Reading, MA (US); Eliot Edward Scull, Andover, MA (US)

(21) Appl. No.: 18/109,700

(22) Filed: Feb. 14, 2023

(51) Int. Cl. H01R 24/54; H01R 24/48; H01R 24/50

(52) U.S. Cl. CPC H01R 24/545; H01R 24/48; H01R 24/50; H01R 2201/24

(57) ABSTRACT

An example cable assembly includes a coaxial cable. A layer encases at least part of the coaxial cable. A memory on, or in contact with, the layer, the memory is configured to store calibration data for the coaxial cable.

### TECHNICAL FIELD

This specification describes example implementations of a cable assembly containing self-calibration data.

### BACKGROUND

A device interface board (DIB) may have multiple sites, each for holding a device under test (DUT) to be tested by a test instrument. Coaxial cables may carry radio frequency (RF) signals to the DIB for transmission to many DUTs and their many pins. Materials, manufacturing, bends in the cables, and environmental factors may affect how each cable transmits the RF signals. The effects may be different for different cables.

### SUMMARY

An example cable assembly includes a coaxial cable. A layer encases at least part of the coaxial cable. A memory on, or in contact with, the layer, the memory is configured to store calibration data for the coaxial cable. The cable assembly may include one or more of the following features, either alone or in combination.

The layer may be configured to protect the coaxial cable from alteration or damage. The layer may include plastic. The layer may be configured to prevent the coaxial cable from bending. The memory, using 3D printing, may be positioned around the coaxial cable. One or more contacts may be connected to the memory. The memory may be readable via the one or more contacts. One or more wires may supply power and signals for data transmission. The layer may be over the one or more wires. The memory may be configured to enable reading over a wireless connection. The memory may include a read-only memory device or a read-write memory device. The memory may include an electrically erasable programmable read-only memory (EEPROM). The cable may be configured to transmit radio frequency (RF) signals. The calibration data may include S-parameters that are specific to the cable and that are based on one or more bends in the cable.

An example test system includes one or more test instruments for performing testing on a device under test (DUT) by transmitting signals to the DUT using the cable assembly such as those described above. One or more processing devices may read the calibration data form the memory. The calibration data may include S-parameters associated with the coaxial cable. At least one of phases or amplitudes of the signals may be based on the calibration data.

An example system for testing a DUT includes cable assemblies connected to a device interface board (DIB) configured to carry signals between a test instrument and the DUT. At least one of the cable assemblies include: a coaxial cable; a layer encasing at least part of the coaxial cable; and memory on, or in contact with, the layer. The memory may be configured to store calibration data for the coaxial cable. The system may include one or more of the following features, either alone or in combination.

The layer may be configured to protect the coaxial cable from alteration or damage. The layer may be or include plastic. The layer may be configured to prevent the coaxial cable from bending beyond a predefined shape or predefined range. The memory, using 3D printing, may be positioned around the coaxial cable. At least one of the cable assemblies may include one or more contacts to the memory. The calibration data may be readable from the memory via the one or more contacts. The memory may be configured to enable reading over a wireless connection. The memory may include a read-only memory device or a read-write memory device. The memory may include an electrically erasable programmable read-only memory (EEPROM). The cable may be configured to transmit radio frequency (RF) signals. The calibration data may be based on losses for corresponding RF frequencies. One or more processing devices may be configured to read the calibration data from the memory, and to apply the calibration data to one or more radio frequency (RF) signals transmitted over the coaxial cable. The cable may be a radio frequency (RF) cable and the calibration data may include S-parameters for the cable.

Any two or more of the features described in this specification, including in this summary section, may be combined to form implementations not specifically described in this specification.

At least part of the devices, systems, and processes described in this specification may be configured or controlled by executing, on one or more processing devices, instructions that are stored on one or more non-transitory machine-readable storage media. Examples of non-transitory machine-readable storage media include read-only memory, an optical disk drive, memory disk drive, and random access memory. At least part of the devices, systems, and processes described in this specification may be configured or controlled using a computing system comprised of one or more processing devices and memory storing instructions that are executable by the one or more processing devices to perform various control operations. The devices, systems, and processes described in this specification may be configured, for example, through design, construction, composition, arrangement, placement, programming, operation, activation, deactivation, and/or control.

The details of one or more implementations are set forth in the accompanying drawings and the following description. Other features and advantages will be apparent from the description and drawings, and from the claims.

### DESCRIPTION OF THE DRAWINGS

FIGS. 1A to 1C are perspective views of example cable assemblies for carrying signals between a test instrument and a device under test (DUT).

FIG. 2 is a block diagram showing components of an example test system for testing a DUT.

FIG. 3 is a flowchart showing an example process for implementing a cable assembly.

FIG. 4 is a flowchart showing an example process for installing a cable assembly.

FIG. 5 is a diagram of an example interface for retrieving data from a memory device and for storing the data on the tester for use by the tester.

FIG. 6 is a diagram of an example interface for inputting data into a memory device during the cable manufacture.

FIG. 7 is a block diagram showing components of example automatic test equipment (ATE).

Like reference numerals in different Figures indicate like elements.

### DETAILED DESCRIPTION

An example cable assembly is configured to store calibration data to be used in a test system to address or to remove errors introduced by the assembly into signals sourced to a DUT and/or into signals from the DUT that are measured by the test system. In some implementations, the errors may be removed or addressed using techniques generally described as S-parameter de-embedding.

The example cable assembly includes a coaxial cable having loss and VSWR (Voltage Standing Wave Ratio) non-idealities described by a frequency sweep of 2-port S-parameters for the coaxial cable. A protective layer encases at least part of the coaxial cable. A memory is positioned in contact with the protective layer. The memory is configured to store the calibration data.

An example test system includes one or more cable assemblies of the type described above that are connected to a device interface board (DIB) and that are for routing signals between a test instrument and a device under test (DUT). Interfaces are provided to enable the test system to retrieve calibration data from memory of one or more cable assemblies and, thereafter, to perform de-embedding using that data on signals transmitted over the one or more cable assemblies to improve signal accuracy. The example interfaces may also be used to update the calibration data initially and whenever it is determined that the calibration data contains errors.

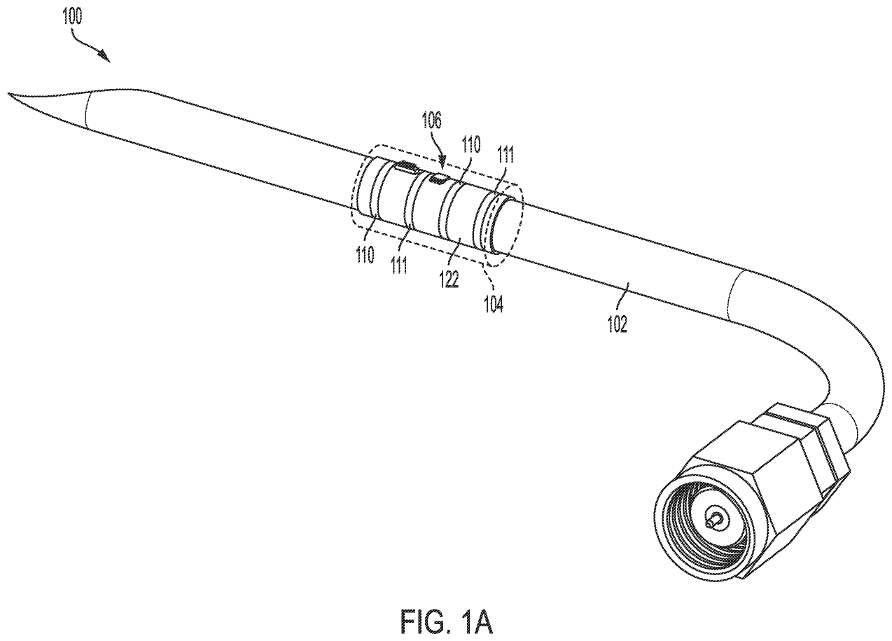

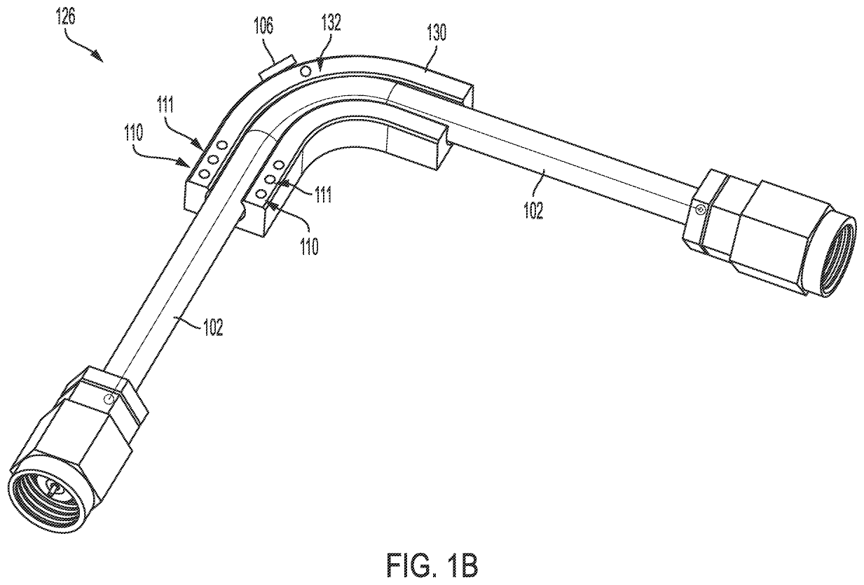

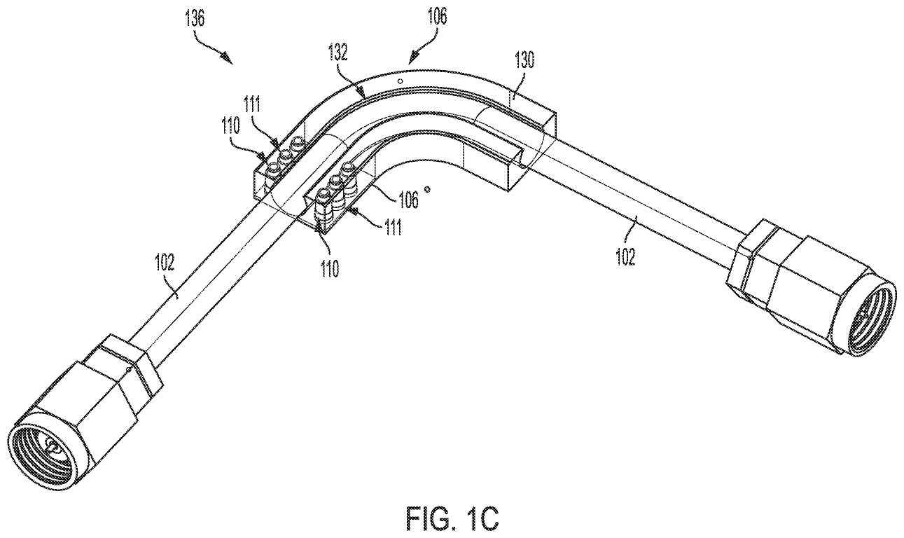

FIG. 1A is a block diagram of an example cable assembly 100. In this example, the cable assembly is configured to carry signals between a test instrument and a DUT; however, the cable assembly may be used to carry other signals in a test system or to carry signals in other types of systems that are unrelated to testing. The cable assembly 100 includes a coaxial cable 102, a protective layer 104, and a memory device 106 located on top of, inside, or below protective layer 104. Coaxial cable 102, protective layer 104, and memory device 106 may be connected to a DIB, over which signals are transmitted between to and from a DUT. For example, the memory device 106 may be attached to, or formed on or in, the protective layer. For example, the memory device may be three-dimensionally (3D) printed on or in the protective layer.

Coaxial cable 102 is configured to transmit radio frequency (RF) signals received from a test instrument to a DIB connected to a DUT, and to transmit response signals from the DUT back to the test instrument. Coaxial cable 102 includes a defined set of S-parameters associated with its reflection coefficient, isolation, and insertion loss. In some implementations, coaxial cable 102 may be configured to transmit signals having frequencies up to frequencies 60 GHz (gigahertz). In some implementations, coaxial cable 102 may be configured to transmit signals having frequencies over frequencies 60 GHz, such as 80 GHz, 100 GHz, 200 GHz, and so forth.

Sticker 122 may be positioned around a peripheral region of coaxial cable 102. Sticker 122 may allow components like memory 106, wires 110 and 111, and/or other electronic components 105 to be placed on coaxial cable 102 without altering, changing the properties of (for example, S parameters), or requiring additional add-ons to coaxial cable 102. Sticker 122 may include plastic or deformable materials. In some implementations, sticker 122 may include an adhesive pad that sticks permanently on coaxial cable 102 and can handle the wear and tear of coaxial cable 102. Sticker 122 may include materials allowing electronic components to operate while positioned on sticker 122.

Protective layer 104 may cover all or part of the coaxial cable and is configured to protect coaxial cable 102 from alteration or damage. For example, protective layer 104 may extend the length of the coaxial cable or protective layer 104 may cover less than the entire length of the coaxial cable. Protective layer 104 may include plastic or deformable materials. In some implementations, protective layer 104 may include hard plastic materials to protect cable assembly 102 when it is to be used in an environment where wear and tear of the coaxial cable 102 are expected. In some implementations, protective layer 104 may extend over sticker 122 to protect the components positioned thereon. Protective layer 104 and/or sticker 102 may be implemented on a flexible printed circuit board fabricated on a flexible substrate like Kapton or other similar materials.

In this regard, coaxial cable 102 may include bends or curves intended by the manufacturer. Protective layer 104 may be used to preserve these bends or curves and to prevent unintended bending due to handling or use from ultimately damaging cable assembly 100. This includes deformations resulting from environmental conditions, e.g., if protective layer 104 is positioned over a bend or in an environment where coaxial cable 104 expands due to increases in temperature.

Memory device 106 is configured to store calibration data for coaxial cable 102. The calibration data may include, e.g., cable calibration identification, manufacture date, and S-parameter data. Other types of information than these listed may be part of the calibration data. Memory device 106 may be a read-only memory device or a read-write memory device. In some examples, memory device 106 may be flash memory. In other examples, memory device 106 may be or include an electrically erasable programmable read-only memory (EEPROM). Memory device 106 may include a combination of different memory devices.

Memory device 106 may be configured to enable access to the stored calibration data. In some examples, one or more wired contacts 110 may be connected to memory 106. Memory device 106 may be readable via the one or more wired contacts 110. Memory device 106 may also enable reading over a wireless connection. For example, memory device 106 may include a transceiver (not shown) that enables communication over a wireless network or that enables direct wireless communication.

Cable assembly 100 may also include one or more wires 111 for supplying power to the memory device and for signaling to and from memory other than, or in addition to, data transmission. Wires 110 and 111 may be under protective device 104, on top of protective device 104, or within protective device 104. Moreover, wires 110 and 111 may be the same type of wire. Wires 110 and 111 may be configured to operate with an 12C bus. In such an arrangement, wires 110 and 111 each may be configured to provide 5V or 3.3V of power, coupled to ground, send serial data, and send serial clock information. Wires 110 and 111 may operate with other serial communication buses. The number of wires 110 and 111 may be more or less as shown depending on signals used by the serial communication bus.

Wires 110 and 111 may be positioned on a peripheral region of sticker 122. Wires 110 and 111 may include a hollow cylindrical shape or other suitable shapes to be positioned on sticker 122. Memory 106 is positioned on sticker 122.

FIG. 1B is a block diagram of another example cable assembly 126. Cable assembly 126 may have the same or similar functionality to cable assembly 100. In this example, a protective layer 130 is on bend 132 of coaxial cable 102. Protective layer 130 protects bend 132 from damage experienced during use. Protective layer 130 may include similar materials as protective layer 114 of FIG. 1A. Protective layer 130 may be sized so that bend 130 fits tightly within. Wires 110 and 111 are positioned within protective layer 130. Memory device 106 is positioned on protective layer 130. The combination of memory devices may store the data described herein.

FIG. 1C is a block diagram of another example cable assembly 136. Cable assembly 136 may have the same or similar functionality as cable assembly 126. In this example, protective layer 130 is made transparent illustrating how wires 110 and 111 may be implemented within protective layer 130. Also, memory device 106 is positioned within protective layer 130 for additional protection. In another implementation, protective layer 130 may partially encase a flexible printed circuit board positioned around coaxial cable 102 at bend 132 using 3D printing. Memory device 106 and wires 110 and 111 are added to the flexible printed circuit board. Afterward, the remaining portions of protective layer 130 may be 3D printed to enclose memory device 106 and wires 110 and 111.

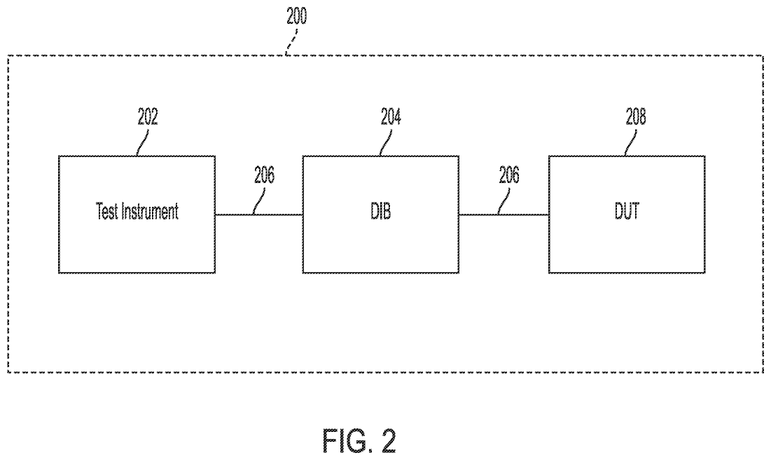

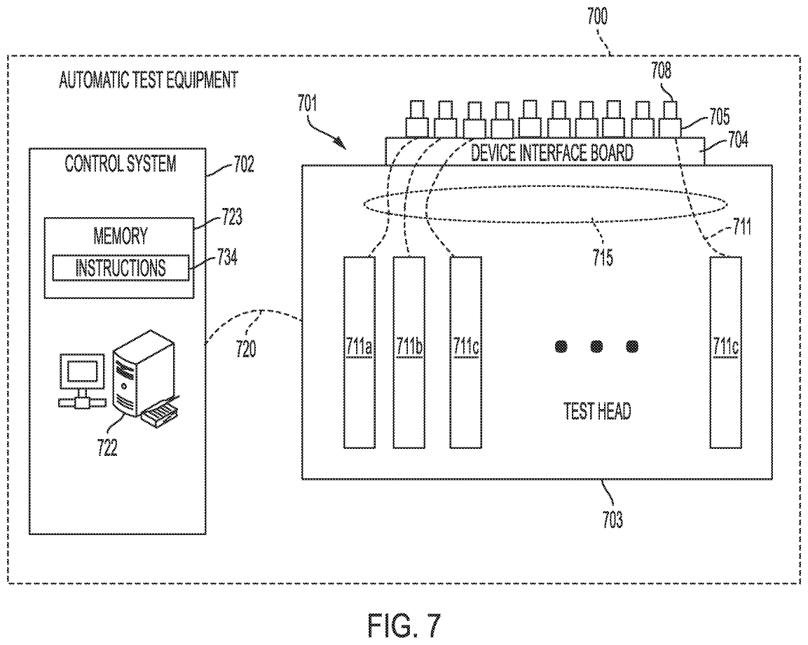

FIG. 2 is a block diagram showing components 200 of an example test system for testing a DUT 208. The components 200 include test instrument 202, DIB 204, and cable assembly 206. Test instrument 202, DIB 204, and cable assembly 206 may be part of automatic test equipment (ATE) 700 (see FIG. 7) used to test DUT 208. Cable assembly 206 may connected to, be located on, or be part of, DIB assembly 204.

Test instrument 202 may output RF signals to DUT 208 via a coaxial cable in cable assembly 206 or 204 or both. The RF signals may include test signals with which to stimulate DUT 208 or to measure signals originating from DUT 208. In some cases, the test signals may be initiated by a control system connected to test instrument 202. The test signals may include instructions, commands, data, parameters, variables, test patterns, and/or any other information designed to elicit a response(s) from DUT 208. In some implementations, multiple test instruments, such as test instrument 202, may be used to output test signals to different DUTs, such as DUT 208, which are distributed in locations on the DIB or wafer, etc. Test instrument 202 may use multiple channels created by one or more cable assemblies 206 to enable communication between the test instruments and DUTs.

DIB 204 may be connected to cable assembly 206 to receive the RF signals therefrom. DUT 208 may be connected to DIB 204 via mechanical and electrical interfaces to establish a physical and electrical connection allowing DIB 204 to pass the RF signals to DUT 208. Cable assembly 206 may include the features of cable assembly 100, 126, and/or 136 described above. In some implementations, cable assembly 206 may be or include a bundle of cable assemblies, each incorporating the elements of cable assembly 100, 126, and/or 136. In some implementations, the test system may obtain calibration data from the memory device of each cable assembly and use the calibration data to perform corrections on the test system by de-embedding the cables from the measured or sourced waveform. For example, the test system may perform the calibrations to account for any incongruities or inconsistencies in the cable assembly relative to other such cable assemblies that are connected to the test system.

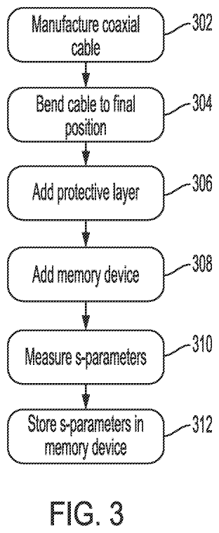

FIG. 3 shows operations included in an example process 300 for manufacturing a cable assembly like assembly 100 (126 or 136). Example process 300 includes operations that the cable manufacturer of a cable assembly may perform.

Process 300 includes the cable manufacturer manufacturing (302) coaxial cable 102. The cable manufacturer may use commonly known techniques to form coaxial cable 102. This may involve forming an inner conductor surrounded by a concentric conducting shield, with the two separated by a dielectric (insulating material). The inner conductor may be constructed of pure copper, copper-coated steel, or aluminum. The cable manufacturer may use materials besides those described to construct the inner conductor. The inner conductor is responsible for transmitting the coaxial cable's signals. The dielectric may include foamed polyethylene (FPE), Teflon, polyethylene (PE), polypropylene (PP), or polyvinyl chloride (PVC). The dielectric may include other materials besides those described herein.

After the coaxial cable 102 is formed, the cable manufacturer conforms (304) coaxial cable 102 to a final configuration. In some cases, coaxial cable 102 may be bent at one or more locations along coaxial cable 102. By bending coaxial cable 102, its original S-parameters may change, resulting in coaxial cable 102 having different S-parameters when compared to a straight version of the coaxial cable. Depending on the use of the coaxial cables, bends are used to provide an easier connection between endpoints. In some implementations, coaxial cables are not bent below the minimum recommended bend radius. Otherwise, the bends may cause ripples and stretching in the cable sheath and dielectric changes. The bend radius may be based on the materials used to make coaxial cable 102. Depending on the usage of coaxial cable 102, the cable manufacturer may select materials based on the bend radius requirements of DIB 204 and/or test instrument 202 to minimize, or to reduce the chances of, damage to coaxial cable 102 and the testing system.

The cable manufacturer adds (306) a protective layer, such as protective layer 104 or 130, over all or part of coaxial cable 102. Protective layer 104 or 130 may be formed on coaxial cable 102 using deposition techniques or 3D printing. In some implementations, protective layer 104 or 130 may be positioned over one or more bends of coaxial cable 102 to protect one or more bends from movement after assembly. In some implementations, protective layer 104 or 130 may be over the entire length of the coaxial cable—from one termination point (coaxial connection) to the other termination point (coaxial connection) on the cable. The protective layer may also enclose, or contact to, the memory device.

The cable manufacturer attaches (308) memory device 106 on, in, or below protective layer 104 or 130 to form cable assembly 100 so that the memory device 106 is in contact with the protective layer. This may be done before, after, or during application of the protective layer to the coaxial cable. Memory device 106 may be positioned on, in, or over the protective layer 104 or 130, as noted. Memory device 106 may include materials that permit a portion of memory device 106 to be set on or be in contact with protective layer 104 or 130. An example material that may be used is an adhesive compatible with protective layer 104 or 130 and placed on memory device 106 to keep it attached to protective layer 104 or 130. In some instances, the adhesive may be placed on protective layer 104 or 130. The cable manufacturer may use materials other than those mentioned to position memory device 106 on or in contact with protective layer 104 or 130. The cable manufacturer may use 3D printing to attach memory 106 on, in, or below protective layer 104 or 130.

In implementations where there are wired connections to the memory device, the wired connections may be located on, in, or below the protective layer. For example, protective layer 104 or 130 may be positioned over wires used by coaxial cable 102 for powering and reading data from memory device 106 to protect these wires. The wires may be incorporated into the cable assembly at the same time as the memory.

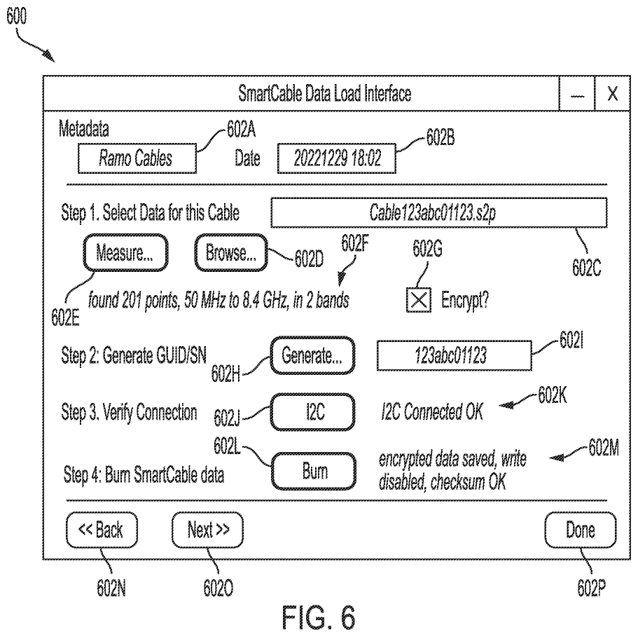

The S-parameters of cable assembly 100 may vary due to the additions of bends. Whether formed to shape or straight, to reflect the correct S-parameters for cable assembly 100, the cable manufacturer measures (310) the S-parameters of cable assembly 100. Operation 312 may be performed by writing to the memory device 106 directly or in communication with an example interface 600 that executes 310 and 312, which is described further below in FIG. 6. In some implementations, operation 310 and example interface 600 may be implemented as machine-executable code and executed on a computing system at the cable manufacturer.

In some implementations, the cable manufacturer may use a Vector Network Analyzer (VNA). The VNA may measure S-parameters over frequency by sweeping the input frequency. The VNA may separate transmitted and reflected power using directional couplers for power measurements. The VNA may be calibrated prior to the measurements using known techniques appropriate to the frequency band.

In some implementations, a time domain reflectometer (TDR) may be used to measure the S-parameters. The measured S-parameters may be stored temporarily in storage. The temporary storage may be in the local storage of either the VNA or TDR. In some cases, the measured S-parameters may be uploaded to a computer system for temporary storage prior to loading into memory device 106.

Afterward, the cable manufacturer may store (312) the measured S-parameters in memory device 106 as part of the calibration data of cable assembly 100. The test system 200 may use the calibration data to calibrate signals in cable assembly 100. The calibration data may include other metadata or information, such as cable calibration identification and manufacturing information. Examples of calibration data that may be stored in memory device 106 may include, but is not limited to, a presence of encryption, manufacturer, date of manufacture, wire type, connector type, nominal length (in meters), customer, cable serial number, a checksum, S-parameter chunks with S-parameters such as: a number of points (linear sweep), start frequency, stop frequency, RI or MA format, s11, s12, s21, s22, and parameters of an equation fitting S-parameter data. Different types of information than those described may be part of the calibration data. The data may be stored in memory 106 over one or more wired connections or over a wireless connection, as described herein.

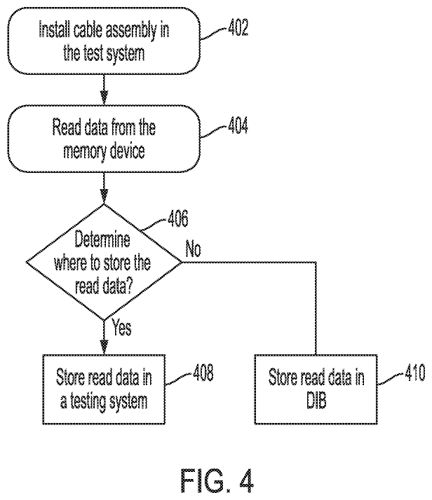

FIG. 4 shows operations included in an example process 400 for installing cable assembly 100 in a tester. Example process 400 includes operations that may be performed at test system 200. In some implementations, at least part of example process 400 may be implemented using machine-executable code that is executed on a control system of testing system 200.

Process 400 includes installing (402) a cable assembly in the test system 200. The cable assembly may be installed by connecting it to DIB 204 and to a test instrument. For example, the installation of cable assembly 100 at the test system may include connecting test instrument 202, at one end of cable assembly 100 and to the DIB at the other end thereof. In some implementations, several cable assemblies, such as cable assembly 100, 100, 126, 136 and/or 206, may be installed at DIB 204 of test system 200.

As the cable assembly is installed, process 404 reads (404) data from the memory device. The S-parameters and/or other calibration data may be read from memory device 106. For example, the S-parameters and/or other calibration data may be read wirelessly or over a wired connection, as described herein Process 400 includes determining (406) where to store the read data. For example, in some implementations, one may store S-parameters or other read data in a local file on testing system 200 or non-volatile memory on DIB 204. The user may input the location for storing the read data via a user interface. The user interface may send the location to process 400 for processing. One example of the user interface may be example user interface 500 described further below.

If the location to store the read data is testing system 200, process 400 stores (408) the read data in the local file on testing system 200 or links to files on testing system 200. If the location to store the read data is the non-volatile memory on DIB 204, process 400 stores (410) the read data in the non-volatile memory on DIB 204. The non-volatile memory may be an EEPROM.

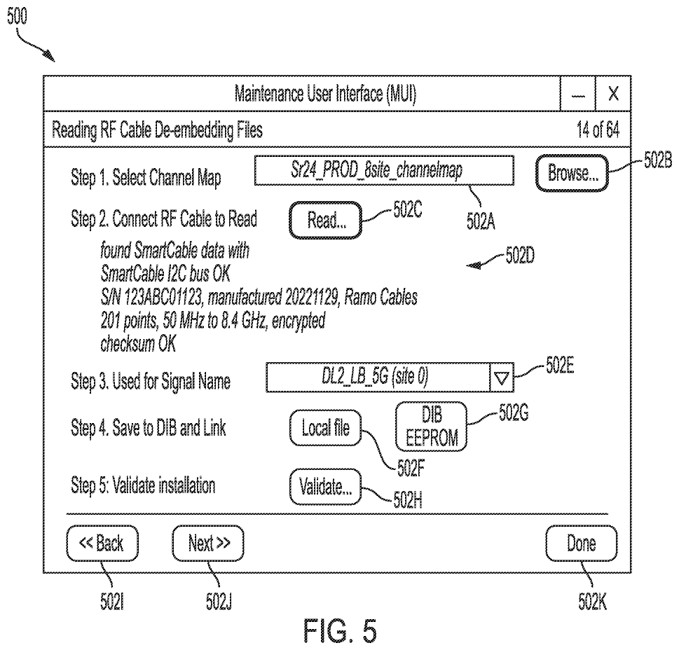

FIG. 5 is a diagram of an example user interface 500 for retrieving de-embedding S-parameter data from a memory of a cable assembly, such as memory device 106. Example interface 500 includes interface elements 502 that receive user input (e.g., 502A) or that display information regarding the status of reading data from the memory of a cable assembly (e.g., 502D). In some implementations, example interface 500 may be a graphical user interface (GUI) running on a control system of test system 200. In some implementations, example interface 500 may be a GUI executing on a computing system separate from test system 200 or its control system. In some implementations, example interface 500 may be implemented by executing a test program used by test system 200 for performing testing.

Input field 502A may be used to input a name and/or location associated with a channel map of DIB 202. The channel map may identify RF pins and sites operated by DIB 202 to manage one or more DUTs, like DUT 208. The channel map may also be stored in the memory on DIB 202 or test system 200. If the channel map is stored and accessible, browse button 502B may be used to access the channel map from memory. In this case, example interface 500 may provide a listing of directories for browsing (502B) to find the channel map. After the channel map is found, the location of the channel map is populated in data field 502A and used to prompt the user during installation. After a data bus is connected to memory device 106, read button 502C may be used to check the status of memory device 106 and determine if it is ready to upload. When read button 502C is activated, display field 502D may display the status of memory device 106, data bus, and calibration data.

Input field 502E may be used to designate the name of signals at each site included on the DIB as defined in the channel map and also used by the test program. The naming convention for the signals at each site may be different for different test systems. Example interface 500 may use buttons 502F and 502G to designate where to store the calibration data read from cable assembly 100 in test system 200. When button 502F or 502G are activated, to the data retrieved from the smart cable is stored in a file system of the test system and its name is linked for that specific signal path. In some implementations when 502G is chosen, the calibration data from the cable assembly 100 may be stored to non-volatile memory located on 204 of test system 200. In some implementations, other non-volatile memories used by DIB 204 may store the calibration data.

Before storing the calibration data, example interface 500 may initiate validation of the calibration data to determine if the calibration data includes errors. In this case, button 502H may be activated to initiate the validation process. In some implementations, the S-parameters are validated by the test system as described above, but example interface 500 may initiate validation of other calibration data. As described previously, the validation process may measure respective S-parameter ports and check that the measured/estimated length is consistent with cable assembly 100, as described in operation 406. This may include comparing the calibration data read from memory device 106 to the measured S-parameters of the validation process. If errors are detected in the calibration data, the validation process may reject the cable or assist the user in measuring it as in steps 310, 312. Otherwise, the calibration data may be stored. Once the calibration data for the path has been stored, button 502J can be used to move to the next signal path listed in the selected channel map. When all signal paths have been completed, button 502K may be activated to indicate the completion of the retrieval and validation process of the calibration data. Button 502I can be used to return to a prior signal path to correct entries.

When a bundle of cable assemblies is used, each cable assembly, such as cable assembly 100, 126, 136, or 206, may have its own respective calibration data. In this case, example interface 500 may assign a retrieval page for each cable assembly installed at test system 200. The retrieval page may include the same information shown in example interface 500, but each cable assembly has different retrieval information for their respective interface elements 502. One may move forward or backward thru the list of cable assemblies by activating buttons 502I or 502J to view or add information for a particular cable assembly.

FIG. 6 is a schematic diagram of an example user interface 600 for inputting data, including calibration data, into the memory device of a cable assembly, such as memory device 106, in operations 310, 312. Example interface 600 includes interface elements 602 that take input or that display information regarding the status of input data into memory device 106. In some implementations, example interface 600 may be or include a general user interface (GUI) running on a computer system at a cable manufacturer.

Input fields 602A and 602B may be used to input metadata like the manufacturer, a name assigned to the cables, and the date. The input metadata may include optional encryption if needed, manufacturer, date of manufacture, wire type, connector type, nominal length (m), customer, cable serial number, checksum, S-parameter chunks with S-parameters such as number of points (linear sweep), start frequency, stop frequency, RI or MA format, s11, s12, s21, and/or s22. In some implementations, input fields 602A and 602B may include more information than those described.

Input field 602C may be used to input a name and/or location of the file associated with the calibration data of a cable assembly. The buttons 602E and 602D allow the user to generate a new file (Measure) or use an existing file (Browse). The cable data of the cable assembly may include additional information like wire type, connector type, or nominal length (m). Example interface 600 may store the cable data in the memory of a computing system located at a cable manufacturer. If the cable data of the cable assembly is stored and accessible, browse button 602B may be used to access the cable data of the cable assembly. In this case, example interface 600 may provide a listing of directories for browsing to find the cable data. Once the cable data is found, the location of the cable data is automatically populated in data field 602C.

When button 602E is activated, example interface 600 may measure or otherwise compute S-parameters for cable assembly 100. Example interface 600 may initiate a VNA or TDR to measure or compute the S-parameters. After completion of its operations, the VNA or TDR may send to example interface 600 the S-parameters for uploading into memory device 106 via wires or wirelessly. Certain results of the operations performed by the VNA and TDR may be displayed in display field 602F.

Checkbox 602G may allow encryption of the S-parameters, including other calibration data, when checked. The encryption used may be asymmetric encryption or symmetric encryption. Asymmetric encryption may use a key pair: a different key may be used for the encryption and decryption process. One of the keys may be typically known as the private key, and the other is known as the public key. The cable manufacturer may keep the private key secret, and the public key is shared amongst authorized test systems. The same key may be used for encryption and decryption in symmetric encryption. When checkbox 602G is not checked, no encryption is used.

Button 602H may be used to generate a global unique identifier (GUID) for cable assembly 100. The GUID may also function as a serial number of cable assembly 100. Example interface 600 may use any of the numerous approaches to generate GUID. When button 602H is activated, the GUID may be displayed in display field 602I. Moreover, cable assembly 100 may be assigned as a serial number the GUID displayed in display 602I.

Button 602J may be used to verify the connection between memory device 106 of cable assembly 100 and a data bus before attempting to program the device. To determine if memory device 106 is ready or capable of receiving calibration data, the cable manufacturer may send via the data bus a signal to memory device 106 requesting acknowledgment by memory device 106 of being connected to the data bus or attempt to read/write one or more memory locations. When button 602J is activated, the connection between memory device 106 and the data bus is checked and the results of that is displayed in field 602K.

Once a positive indication of the connection between memory device 106 and the data bus, memory device 106 may be ready to receive the S-parameters and other calibration data for storage. Button 602L may be used to upload, e.g., to memory device 106. the S-parameters and other calibration data. When button 602L is activated, example interface 600 may display the status of the operation for uploading to memory device 106 the S-parameters and other calibration data in display field 602M. This includes showing the status of the checksum and additional information. For example, if the data doesn't fit in the device memory or a readback doesn't match, an error can be indicated.

After there is a positive indication of the storage of the S-parameters and other calibration data in memory device 106, button 602P may be activated to indicate the completion of the calibration data storage.

When many cable assemblies are manufactured each cable assembly, such as cable assembly 100, may have its respective calibration data. The manufacturer may use 602N, 602O to step through the testing and data storage of each one.

If desired, a single cable assembly with multiple cables can have de-embedding data stored in a single tag having a protective layer and memory such as protective layer 104 and memory 106. In this case, example interface 600 may assign a storage page for each cable assembly to be installed at test system 200. The storage page may include the same information shown in example interface 600, but each cable assembly has different storage information for their respective interface elements 602. Similarly, the process for manufacturing many cables, one may move forward or backward thru the list of cable assemblies by activating buttons 602N or 602O to view or add information for a particular cable assembly.

FIG. 7 is a block diagram showing components of example ATE 700 that includes a testing device (referred to herein as a “tester”) 701 and a control system 702. The components 100, 126, or 136 described above may be part of ATE 700.

Tester 701 includes a test head 703 and a device interface board (DIB) 704 connected physically and electrically to test head 703. DIB 704 may be an implementation of DIB 204 of FIG. 2. In this example, DIB 704 includes a circuit board that includes mechanical and electrical interfaces at sites 705. One or more DUTs, such as DUT 708, connect to each of those sites for testing by the ATE. DUT 708 may be an implementation of DUT 208 of FIG. 2.

DIB 704 may include, among other things, connectors, conductive traces, conductive layers, and circuitry for routing signals between test instruments in the test head 703, DUTs connected to DIB sites, and other circuitry in the ATE. Power, including voltage and current, may be run via one or more layers in the DIB 704 to DUTs connected to the DIB.

Test head 703 includes multiple test instruments 711a to 711n, each of which may be configured, as appropriate, to implement testing and/or other functions. Although only four test instruments are shown, ATE 10 may include any appropriate number of test instruments, including one or more residing outside of test head 715. The test instruments may be hardware devices that may include one or more processing devices and/or other circuitry. The test instruments may be configured—for example, programmed—to output commands to test DUTs held on the DIB 704. The commands to test the DUTs may be or include instructions, signals, data, parameters, variables, test patterns, and/or any other information designed to elicit response(s) from the DUT. One or more—for example, all of—the test instruments may be configured to receive, from the DUT, responses to the commands sent from the ATE to the DUT. The responses are in the form of response data. The test instruments may be configured to analyze the response data to determine whether the DUT has passed or failed testing. Each test instrument 711a to 711n may be an instance of test instrument 202.

In addition, the test system may include cable assemblies 715, an example of which is of includes cable assembly 100, 126, 136, or 206 for delivering signals between the DUTs on DIB 704 and test instruments 711a to 711n. Each test instrument 711a to 711n may use one or more cable assemblies, like cable assembly 100, 126, 136, or 206, to deliver and receive signals from DIB 704. In this regard, test channels are configured between the test head and the DIB on the cable assemblies 715 enable communication between the DUTs and the test instruments using one or more cable assemblies 206. Although only four test channels are shown in FIG. 7, any number of test channels may be included, e.g., one or more test channels per DUT.

Control system 702 is configured to—e.g., programmed to—communicate with test instruments 711a to 711n to direct and/or to control testing of the DUTs. In some implementations, this communication 720 link may be over direct connection such as a high-speed serial bus of the type described herein. In some implementations, this communication link may be over a network. In some implementations, this communication link may be considered part of one or more of the test channels. In some implementations, this communication link may not be considered part of one or more of the test channels. In some implementations, this link may include a cable assembly like that of 100, 126, 136, or 206.

Control system 702 may be configured to provide test programs and/or commands to test instruments 711a to 711n in the test head, which the test instrument(s) use to test the DUTs. Control system 702 may be configured to receive response data from test instrument(s) and to analyze the response data to determine whether DUTs have passed or failed testing. Memory 723 also stores machine-executable instructions 734, such computer code in binary executable form, to implement all or part of functions performed by control system 702. The machine-executable instructions 734 may include the instructions for performing the operations of example interface 600. In some implementations, the machine-executable instructions 734 may include the instructions for performing the operations of process 400.

All or part of the test systems and processes described in this specification and their various modifications may be configured or controlled at least in part by one or more computers such as control system 702 using one or more computer programs tangibly embodied in one or more information carriers, such as in one or more non-transitory machine-readable storage media. A computer program can be written in any form of programming language, including compiled or interpreted languages, and it can be deployed in any form, including as a stand-alone program or as a module, part, subroutine, or other unit suitable for use in a computing environment. A computer program can be deployed to be executed on one computer or on multiple computers at one site or distributed across multiple sites and interconnected by a network.

Actions associated with configuring or controlling the test system and processes described herein can be performed by one or more programmable processors executing one or more computer programs to control or to perform all or some of the operations described herein. All or part of the test systems and processes can be configured or controlled by special purpose logic circuitry, such as, an FPGA (field programmable gate array) and/or an ASIC (application-specific integrated circuit) or embedded microprocessor(s) localized to the instrument hardware.

Processors suitable for the execution of a computer program include, by way of example, both general and special purpose microprocessors, and any one or more processors of any kind of digital computer. Generally, a processor may receive instructions and data from a read-only storage area or a random access storage area or both. Elements of a computer include one or more processors for executing instructions and one or more storage area devices for storing instructions and data. Generally, a computer will also include, or be operatively coupled to receive data from, or transfer data to, or both, one or more machine-readable storage media, such as mass storage devices for storing data, such as magnetic, magneto-optical disks, or optical disks. Non-transitory machine-readable storage media suitable for embodying computer program instructions and data include all forms of non-volatile storage area, including by way of example, semiconductor storage area devices, such as EPROM (erasable programmable read-only memory), EEPROM (electrically erasable programmable read-only memory), and flash storage area devices; magnetic disks, such as internal hard disks or removable disks; magneto-optical disks; and CD-ROM (compact disc read-only memory) and DVD-ROM (digital versatile disc read-only memory).

Elements of different implementations described may be combined to form other implementations not specifically set forth previously. Elements may be left out of the systems described previously without adversely affecting their operation or the operation of the system in general. Furthermore, various separate elements may be combined into one or more individual elements to perform the functions described in this specification.

Other implementations not specifically described in this specification are also within the scope of the following claims.

What is claimed is:

1. A cable assembly comprising:
a coaxial cable;
a layer encasing at least part of the coaxial cable; and
memory on, or in contact with, the layer, the memory being configured to store calibration data for the coaxial cable.

2. The cable assembly of claim 1, wherein the layer is configured to protect the coaxial cable from alteration or damage.

3. The cable assembly of claim 1, wherein the layer comprises plastic.

4. The cable assembly of claim 1, wherein the layer is configured to prevent the coaxial cable from bending.

5. The cable assembly of claim 1, the memory, using 3D printing, is positioned around the coaxial cable.

6. The cable assembly of claim 1, further comprising:
one or more contacts connected to the memory, the memory being readable via the one or more contacts.

7. The cable assembly of claim 1, further comprising:
one or more wires for supplying power and signals for data transmission, the layer being over the one or more wires.

8. The cable assembly of claim 1, wherein the memory is configured to enable reading over a wireless connection.

9. The cable assembly of claim 1, wherein the memory comprises a read-only memory device or a read-write memory device.

10. The cable assembly of claim 1, wherein the memory comprises an electrically erasable programmable read-only memory (EEPROM).

11. The cable assembly of claim 1, wherein the cable is configured to transmit radio frequency (RF) signals, and wherein the calibration data comprises S-parameters that are specific to the cable and that are based on one or more bends in the cable.

12. A system for testing a device under test (DUT), the system comprising:
cable assemblies connected to a device interface board (DIB) configured to carry signals between a test instrument and the DUT, at least one of the cable assemblies comprising:
a coaxial cable;
a layer encasing at least part of the coaxial cable; and
memory on, or in contact with, the layer, the memory being configured to store calibration data for the coaxial cable.

13. The system of claim 12, wherein the layer is configured to protect the coaxial cable from alteration or damage.

14. The system of claim 12, wherein the layer comprises plastic.

15. The system of claim 12, wherein the layer is configured to prevent the coaxial cable from bending beyond a predefined shape or predefined range.

16. The system of claim 12, wherein the memory, using 3D printing, is positioned around the coaxial cable.

17. The system of claim 12, wherein at least one of the cable assemblies comprises one or more contacts to the memory; and
wherein the calibration data is readable from the memory via the one or more contacts.

18. The system of claim 12, wherein the memory is configured to enable reading over a wireless connection.

19. The system of claim 12, wherein the memory comprises a read-only memory device or a read-write memory device.

20. The system of claim 12, wherein the memory comprises an electrically erasable programmable read-only memory (EEPROM).

21. The system of claim 12, wherein the cable is configured to transmit radio frequency (RF) signals, and wherein the calibration data is based on losses for corresponding RF frequencies.

22. The system of claim 12, further comprising:
one or more processing devices configured to read the calibration data from the memory, and to apply the calibration data to one or more radio frequency (RF) signals transmitted over the coaxial cable.

23. The system of claim 12, wherein the cable is a radio frequency (RF) cable and the calibration data comprises S-parameters for the cable.

24. A test system comprising:
one or more test instruments for performing testing on a device under test (DUT) by transmitting signals to the DUT using the cable assembly of claim 1; and
one or more processing devices to perform operations comprising:
reading the calibration data form the memory, the calibration data comprising S-parameters associated with the coaxial cable;
wherein at least one of phases or amplitudes of the signals is based on the calibration data.
